(19) United States
(12) Patent Application Publication
(10) Pub. No.: US 2021/0351327 A1
(43) Pub. Date: Nov. 11, 2021

(54) LIGHT-SOURCE APPARATUS AND DISTANCE MEASUREMENT APPARATUS

(71) Applicant: DENSO CORPORATION, Kariya-city (JP)

(72) Inventor: Kosuke NIIMURA, Kariya-city (JP)

(21) Appl. No.: 17/382,827

(22) Filed: Jul. 22, 2021

Related U.S. Application Data
(63) Continuation of application No. PCT/JP2020/001866, filed on Jan. 21, 2020.

(30) Foreign Application Priority Data
Jan. 25, 2019 (JP) 2019-011446

(51) Int. Cl. H01L 33/48; H01L 33/52; H01L 33/64

(52) U.S. Cl. CPC H01L 33/486; H01L 33/644; H01L 33/52

(57) ABSTRACT

A light-source apparatus includes a light-source chip, a case, a substrate, an electromagnetic shield plate and a thermally-conductive member. The light-source chip is received in the case. The case is mounted to the substrate. The electromagnetic shield plate covers at least part of the substrate. The thermally-conductive member is arranged to abut both the case and the electromagnetic shield plate.

### CROSS-REFERENCE TO RELATED APPLICATIONS

The present application is a continuation application of International Application No. PCT/JP2020/001866 filed on Jan. 21, 2020, which is based on and claims priority from Japanese Patent Application No. 2019-011446 filed on Jan. 25, 2019. The entire contents of these applications are incorporated by reference into the present application.

### BACKGROUND

### 1 Technical Field

The present disclosure relates to a light-source apparatus and a distance measurement apparatus that includes the light-source apparatus.

### 2 Description of Related Art

There is disclosed, for example in Japanese Patent No. JP 5391753 B2, a light-source apparatus that includes a light-source chip.

### SUMMARY

According to the present disclosure, there is provided a light-source apparatus which includes a light-source chip, a case, a substrate, an electromagnetic shield plate and a thermally-conductive member. The light-source chip is received in the case. The case is mounted to the substrate. The electromagnetic shield plate covers at least part of the substrate. The thermally-conductive member is arranged to abut both the case and the electromagnetic shield plate.

### BRIEF DESCRIPTION OF THE DRAWINGS

FIG. 1 is a block diagram illustrating the overall configuration of a distance measurement apparatus according to a first embodiment.

FIG. 2 is an exploded perspective view illustrating the configuration of a light-source apparatus according to the first embodiment.

FIG. 3 is a schematic cross-sectional view of the light-source apparatus taken along the line in FIG. 2.

FIG. 4 is a plan view of a light-source unit of the light-source apparatus, omitting a metal lid of the light-source unit.

FIG. 5 is a schematic cross-sectional view of the light-source apparatus, wherein hatching lines are not depicted for the sake of simplicity.

FIG. 6 is an explanatory diagram illustrating both first and second heat dissipation paths formed in the light-source apparatus.

FIG. 7 is a schematic cross-sectional view illustrating the configuration of a light-source unit of a light-source apparatus according to a second embodiment, wherein hatching lines are not depicted for the sake of simplicity.

FIG. 8 is a plan view illustrating the configuration of a main body of an electromagnetic shield plate of the light-source apparatus according to the second embodiment.

FIG. 9 is a plan view illustrating the configuration of a case of the light-source apparatus according to the second embodiment.

### DESCRIPTION OF EMBODIMENTS

There are known light-source apparatuses which include a light-source chip, a case having the light-source chip received therein, and a substrate having the case mounted thereto. However, the inventor of the present application has found, through detailed investigation, that in the known light-source apparatuses, it may be difficult to sufficiently dissipate heat generated by the light-source chip. If the heat generated by the light-source chip could not be sufficiently dissipated, the temperature of the light-source chip would be increased. Consequently, the light output of the light-source chip would be lowered and/or the light-source chip would be deteriorated.

In contrast, in the above-described light-source apparatus according to the present disclosure, there are formed both a first heat dissipation path and a second heat dissipation path, through each of which heat is dissipated from the light-source chip to the outside of the light-source apparatus. The first heat dissipation path sequentially passes through the case, the thermally-conductive member and the electromagnetic shield plate. On the other hand, the second heat dissipation path sequentially passes through the case and the substrate. Consequently, with both the first and second heat dissipation paths formed in the light-source apparatus, it becomes possible to suppress increase in the temperature of the light-source chip. As a result, it becomes possible to suppress both decrease in the light output of the light-source chip and deterioration of the light-source chip.

Exemplary embodiments will be described hereinafter with reference to the drawings. It should be noted that for the sake of clarity and understanding, identical components having identical functions throughout the whole description have been marked, where possible, with the same reference numerals in the drawings and that for the sake of avoiding redundancy, descriptions of identical components will not be repeated.

### First Embodiment

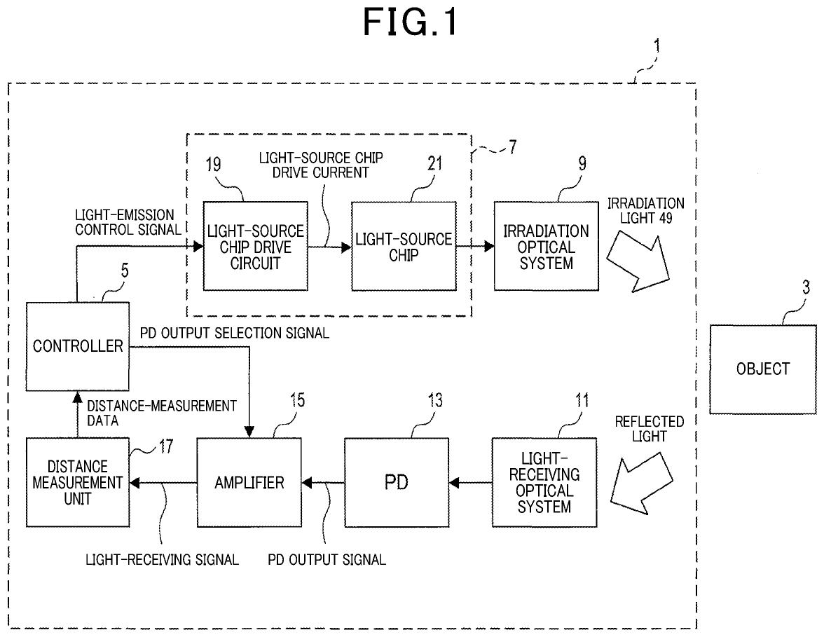

FIG. 1 illustrates the overall configuration of a distance measurement apparatus 1 according to a first embodiment. The distance measurement apparatus 1 is configured to be installed in, for example, a vehicle to measure the distance from the distance measurement apparatus 1 (or from the vehicle) to an object 3. The object 3 is, for example, a target existing in the vicinity of the vehicle.

As shown in FIG. 1, the distance measurement apparatus 1 includes a controller 5, a light-source apparatus 7, an irradiation optical system 9, a light-receiving optical system 11, a photodiode (to be referred to as PD hereinafter) 13, an amplifier 15 and a distance measurement unit 17. Moreover, the light-source apparatus 7 includes a light-source chip drive circuit 19 and a light-source chip 21.

In the present embodiment, the distance measurement apparatus 1 measures the distance from the distance measurement apparatus 1 to the object 3 in the following manner.

First, the controller 5 sends a light-emission control signal to the light-source chip drive circuit 19. Then, the light-source chip drive circuit 19 supplies, according to the light-emission control signal, a light-source chip drive current to the light-source chip 21. Upon the supply of the light-source chip drive current, the light-source chip 21 irradiates an irradiation light 49. Then, the irradiation light 49 reaches the object 3 via the irradiation optical system 9. In addition, the wavelength of the irradiation light 49 may be, for example, in the range of 850 to 950 nm.

The object 3 reflects the irradiation light 49, thereby generating a reflected light. The reflected light reaches the PD 13 via the light-receiving optical system 11. The PD 13 generates a PD output signal according to the reflected light. The amplifier 15 amplifies the PD output signal to generate a light-receiving signal. The controller 5 sends a PD output selection signal to the amplifier 15. The distance measurement unit 17 generates distance-measurement data on the basis of the light-receiving signal. The controller 5 receives the distance-measurement data. Then, the controller 5 calculates the distance from the distance measurement apparatus 1 to the object 3 on the basis of the time difference between the time point at which the light-emission control signal is sent and the time point at which the distance-measurement data is received.

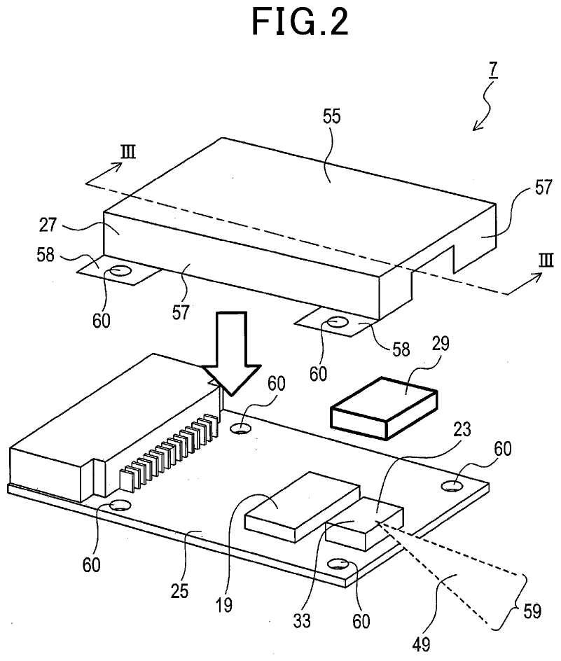

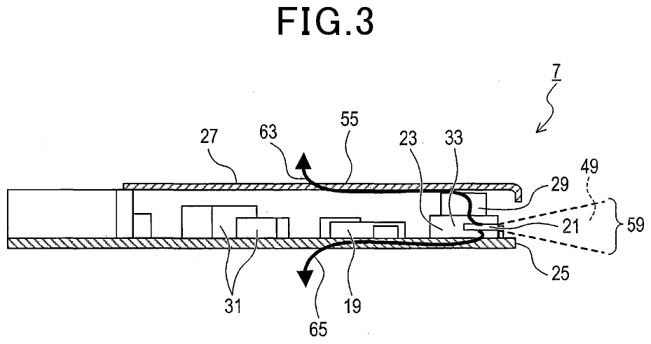

Next, the detailed configuration of the light-source apparatus 7 according to the present embodiment will be described with reference to FIGS. 2-5. As shown in FIGS. 2 and 3, the light-source apparatus 7 includes a light-source unit 23, a substrate 25, an electromagnetic shield plate 27, a thermally-conductive member (or heat conductor) 29 and the aforementioned light-source chip drive circuit 19.

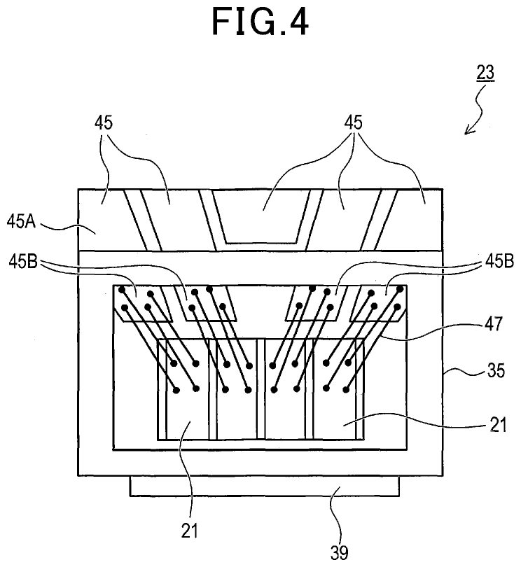

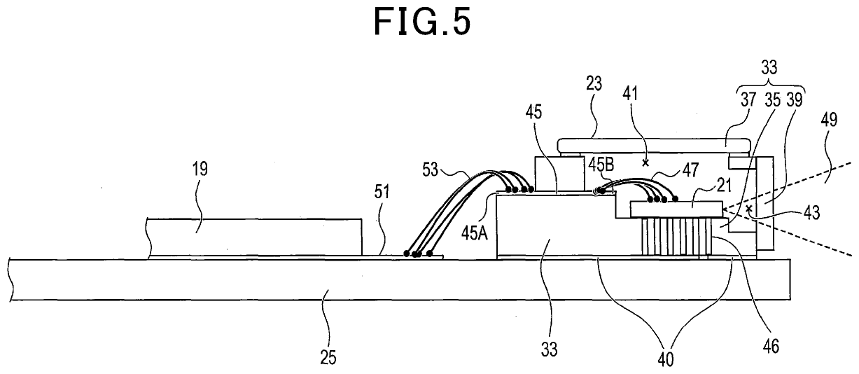

As shown in FIGS. 4 and 5, the light-source unit 23 includes the aforementioned light-source chip 21 and a case 33. The light-source chip 21 may be implemented by, for example, a laser diode.

The case 33 receives the light-source chip 21 therein. As shown in FIG. 5, the case 33 includes a main body 35, a metal lid 37, an exit window 39, a lower electrode pad 40, a plurality of upper electrode pads 45 and vias 46. As shown in FIGS. 4 and 5, the main body 35 is box-shaped and made of ceramic. The main body 35 has both a first opening 41 and a second opening 43, at each of which the main body 35 opens.

The lower electrode pad 40 is formed on a lower surface of the main body 35 which faces the substrate 25. The upper electrode pads 45 are formed in the main body 35 so as to be located away from the substrate 25. Each of the upper electrode pads 45 has a first part 45A located outside the main body 35 and a second part 45B located inside the main body 35. The second part 45B and the light-source chip 21 are connected by a plurality of wires 47. Each of the vias 46 has one end abutting the light-source chip 21 and the other end abutting the lower electrode pad 40.

The metal lid 37 is plate-shaped and made of metal. The metal lid 37 is arranged to close the first opening 41. The exit window 39 is plate-shaped and made of transparent glass. The exit window 39 is arranged to close the second opening 43. The irradiation light 49 irradiated by the light-source chip 21 passes through the exit window 39 and is then directed to the irradiation optical system 9 shown in FIG. 1. In addition, the inside of the case 33 is hermetically sealed and filled with an inert gas.

As shown in FIG. 2, both the light-source unit 23 and the light-source chip drive circuit 19 are mounted on the substrate 25. Moreover, as shown in FIG. 5, the lower electrode pad 40 of the light-source unit 23 is arranged to abut the substrate 25.

Furthermore, as shown in FIG. 5, the substrate 25 has an electrically-conductive layer 51 formed on a surface thereof. The electrically-conductive layer 51 may be, for example, a ground. Both the light-source chip drive circuit 19 and the light-source chip 21 are electrically connected to the electrically-conductive layer 51. The light-source chip drive circuit 19 and the first parts 45A of the upper electrode pads 45 are connected by a plurality of wires 53. Consequently, the light-source chip drive circuit 19 and the light-source chip 21 are electrically connected to each other via the vias 46, the electrically-conductive layer 51, the wires 53, the upper electrode pads 45 and the wires 47.

The electromagnetic shield plate 27 is a member made of metal. As shown in FIG. 2, the electromagnetic shield plate 27 includes a main body 55, side portions 57 and flange portions 58. The main body 55 is rectangular plate-shaped. The side portions 57 are formed respectively at the four sides of the main body 55. Moreover, the side portions 57 each extend in a thickness direction of the main body 55. The flange portions 58 are formed on two of the side portions 57 which face each other. Each of the flange portions 58 extends outward from a lower end of a corresponding one of the side portions 57. Here, the lower ends of the side portions 57 denote the ends of the side portions 57 on the substrate 25 side. The flange portions 58 are arranged to abut the substrate 25. In the flange portions 58 and the substrate 25, there are respectively formed holes 60. The flange portions 58 are fixed to the substrate 25 by fastening fixing members (e.g., screws or bolts) into the holes 60. The electromagnetic shield plate 27 is provided to block noise generated by the light-source chip drive circuit 19 and the like.

As shown in FIG. 3, the main body 55 of the electromagnetic shield plate 27 covers part of the substrate 25. That is, when viewed along the thickness direction of the substrate 25, the main body 55 of the electromagnetic shield plate 27 overlaps part of the substrate 25. Moreover, on that part of the substrate 25 which is covered by the main body 55 of the electromagnetic shield plate 27, there are mounted both the light-source unit 23 and the light-source chip drive circuit 19. Consequently, both the light-source unit 23 and the light-source chip drive circuit 19 are interposed between the substrate 25 and the main body 55 of the electromagnetic shield plate 27.

Furthermore, as shown in FIG. 3, the thermally-conductive member 29 is mounted between the light-source unit 23 and the main body 55 of the electromagnetic shield plate 27. Consequently, the thermally-conductive member 29 abuts both the case 33 of the light-source unit 23 and the main body 55 of the electromagnetic shield plate 27. More specifically, the thermally-conductive member 29 abuts both the metal lid 37 and the main body 35 of the case 33.

The thermally-conductive member 29 may be a solid member or in the form of a paste. In the case of the thermally-conductive member 29 being a solid member, the shape of the thermally-conductive member 29 is not particularly limited. For example, in this case, the thermally-conductive member 29 may have a prismatic shape, a cylindrical shape or a plate shape.

Moreover, in the case of the thermally-conductive member 29 being a solid member, the material of the thermally-conductive member 29 may be, for example, a resin composition that includes silicon and a thermally-conductive filler. Further, the thermally-conductive filler may be, for example, a ceramic filler. On the other hand, in the case of the thermally-conductive member 29 being in the form of a paste, the material of the thermally-conductive member 29 may be, for example, silicone. In addition, silicone is a synthetic polymer compound having a backbone formed by siloxane bonds.

In the present embodiment, the outer surface of the thermally-conductive member 29 is black in color. Moreover, on the outer surface of the thermally-conductive member 29, the reflectivity (or reflectance) to the irradiation light 49, which is irradiated by the light-source chip 21, is lower than or equal to 5%. For example, when the wavelength of the irradiation light 49 is in the range of 850 to 950 nm, the reflectivity of the outer surface of the thermally-conductive member 29 to the irradiation light 49 whose wavelength is in the range of 850 to 950 nm is lower than or equal to 5%.

Furthermore, in the present embodiment, as shown in FIG. 3, the thermally-conductive member 29 is located outside the irradiation region 59 of the irradiation light 49. Here, the irradiation region 59 denotes the region within which the irradiation light 49 is irradiated.

According to the present embodiment, it is possible to achieve the following advantageous effects.

In the present embodiment, the light-source apparatus 7 includes the light-source chip 21, the case 33, the substrate 25, the electromagnetic shield plate 27 and the thermally-conductive member 29. The light-source chip 21 is received in the case 33. The case 33 is mounted to the substrate 25. The electromagnetic shield plate 27 covers part of the substrate 25. The thermally-conductive member 29 is arranged to abut both the case 33 and the electromagnetic shield plate 27.

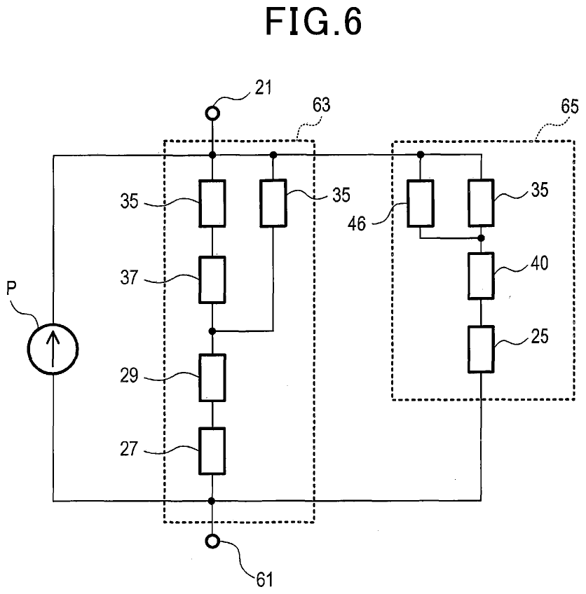

With the above configuration, as illustrated in FIGS. 3 and 6, in the light-source apparatus 7, there are formed both a first heat dissipation path 63 and a second heat dissipation path 65, through each of which heat is dissipated from the light-source chip 21 to the outside 61 of the light-source apparatus 7. In addition, in FIG. 6, “P” represents the amount of heat generated by the light-source chip 21.

More specifically, as illustrated in FIG. 6, the first heat dissipation path 63 includes a heat dissipation path that sequentially passes through the main body 35 of the case 33, the metal lid 37 of the case 33, the thermally-conductive member 29 and the electromagnetic shield plate 27. Moreover, the first heat dissipation path 63 also includes a heat dissipation path that sequentially passes through the main body 35 of the case 33, the thermally-conductive member 29 and the electromagnetic shield plate 27. On the other hand, the second heat dissipation path 65 includes a heat dissipation path that sequentially passes through the main body 35 of the case 33, the lower electrode pad 40 and the substrate 25. Moreover, the second heat dissipation path 65 also includes a heat dissipation path that sequentially passes through the vias 46, the lower electrode pad 40 and the substrate 25.

Consequently, with both the first heat dissipation path 63 and the second heat dissipation path 65 formed in the light-source apparatus 7, it becomes possible to suppress increase in the temperature of the light-source chip 21. As a result, it becomes possible to suppress both decrease in the light output of the light-source chip 21 and deterioration of the light-source chip 21.

Moreover, in the present embodiment, the outer surface of the thermally-conductive member 29 is black in color. Therefore, if stray light caused by the irradiation light 49 is incident on the outer surface of the thermally-conductive member 29, it will be difficult for the outer surface of the thermally-conductive member 29 to reflect the stray light. As a result, it becomes possible to suppress the stray light in the light-source apparatus 7.

In the present embodiment, the reflectivity of the outer surface of the thermally-conductive member 29 to the irradiation light 49, which is irradiated by the light-source chip 21, is lower than or equal to 5%. Therefore, if stray light caused by the irradiation light 49 is incident on the outer surface of the thermally-conductive member 29, it will be difficult for the outer surface of the thermally-conductive member 29 to reflect the stray light. As a result, it becomes possible to suppress the stray light in the light-source apparatus 7.

In the present embodiment, the thermally-conductive member 29 is located outside the irradiation region 59 within which the irradiation light 49 is irradiated. As a result, it becomes possible to prevent the thermally-conductive member 29 from blocking the irradiation light 49.

In addition, the distance measurement apparatus 1 according to the present embodiment includes the light-source apparatus 7 as described above. Therefore, it is possible to achieve the above-described advantageous effects in the distance measurement apparatus 1.

### Second Embodiment

A light-source apparatus 7 according to a second embodiment has the same basic configuration as the light-source apparatus 7 according to the first embodiment. Therefore, only the differences of the light-source apparatus 7 according to the second embodiment from the light-source apparatus 7 according to the first embodiment will be described hereinafter.

In the light-source apparatus 7 according to the first embodiment, that surface of the main body 55 of the electromagnetic shield plate 27 which faces the case 33 is flat in shape. Moreover, that surface of the case 33 which faces the main body 55 of the electromagnetic shield plate 27 is also flat in shape (see FIGS. 2 and 3).

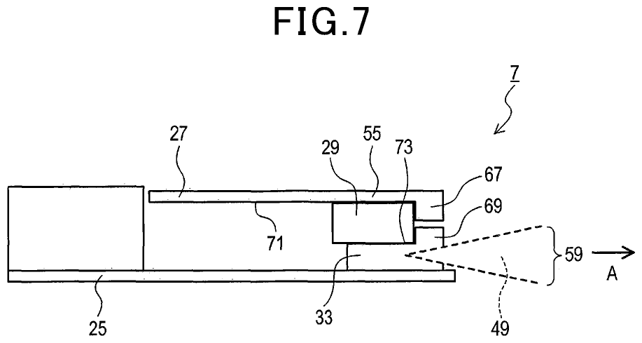

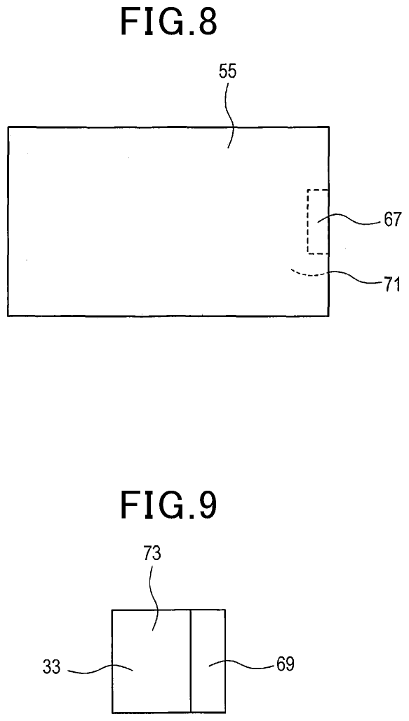

In contrast, in the light-source apparatus 7 according to the second embodiment, as shown in FIGS. 7-9, on that surface of the main body 55 of the electromagnetic shield plate 27 which faces the case 33, there is formed a bank portion (or protruding portion) 67 to protrude toward the case 33. Moreover, on that surface of the case 33 which faces the main body 55 of the electromagnetic shield plate 27, there is formed a bank portion (or protruding portion) 69 to protrude toward the main body 55 of the electromagnetic shield plate 27.

More specifically, in the present embodiment, the bank portion 67 is formed, on the lower surface 71 of the main body 55 of the electromagnetic shield plate 27, at an end of the lower surface 71 on the irradiation region 59 side in the irradiation direction A of the irradiation light 49. Here, of surfaces of the main body 55 of the electromagnetic shield plate 27, the lower surface 71 is that surface of the main body 55 which faces the case 33. The irradiation direction A is the direction in which the irradiation light 49 travels.

On the other hand, the bank portion 69 is formed, on the upper surface 73 of the case 33, at an end of the upper surface 73 on the irradiation region 59 side in the irradiation direction A of the irradiation light 49. Here, of surfaces of the case 33, the upper surface 73 is that surface of the case 33 which faces the main body 55 of the electromagnetic shield plate 27.

Moreover, as shown in FIG. 7, both the bank portion 67 of the main body 55 of the electromagnetic shield plate 27 and the bank portion 69 of the case 33 are located closer to the irradiation region 59 than the thermally-conductive member 29 is. Consequently, if there is movement of the thermally-conductive member 29 toward the irradiation region 59, both the bank portion 67 of the main body 55 of the electromagnetic shield plate 27 and the bank portion 69 of the case 33 will make contact with the thermally-conductive member 29, thereby restraining the movement of the thermally-conductive member 29.

According to the second embodiment, it is also possible to achieve the same advantageous effects as described in the first embodiment.

Moreover, in the light-source apparatus 7 according to the second embodiment, there are formed the bank portions 67 and 69 respectively in the main body 55 of the electromagnetic shield plate 27 and the case 33. Consequently, it becomes possible to restrain, with both the bank portions 67 and 69, movement of the thermally-conductive member 29 toward the irradiation region 59. As a result, it becomes possible to more reliably prevent the thermally-conductive member 29 from blocking the irradiation light 49.

While the above particular embodiments have been shown and described, it will be understood by those skilled in the art that various modifications, changes, and improvements may be made without departing from the spirit of the present disclosure.

For example, in the above-described embodiments, the main body 55 of the electromagnetic shield plate 27 is configured to cover only part of the substrate 25. However, the main body 55 of the electromagnetic shield plate 27 may alternatively be configured to cover the entire substrate 25.

In the above-described embodiments, the main body 35 of the case 33 is made of ceramic. However, the main body 35 of the case 33 may alternatively be made of other materials than ceramic, such as resin.

In the above-described embodiments, the case 33 has the metal lid 37 that is made of metal. However, the case 33 may have, instead of the metal lid 37, a lid that is made of other materials than metal, such as resin.

In the above-described embodiments, the thermally-conductive member 29 is configured so that the entire outer surface of the thermally-conductive member 29 is black in color. However, the thermally-conductive member 29 may alternatively be configured so that part or the whole of the outer surface of the thermally-conductive member 29 is not black in color.

In the above-described embodiments, the thermally-conductive member 29 is configured so that on the entire outer surface of the thermally-conductive member 29, the reflectivity to the irradiation light 49 is lower than or equal to 5%. However, the thermally-conductive member 29 may alternatively be configured so that on part or the whole of the outer surface of the thermally-conductive member 29, the reflectivity to the irradiation light 49 is higher than 5%.

In the above-described embodiments, the light-source apparatus 7 is applied to the distance measurement apparatus 1. However, the light-source apparatus 7 may also be applied to other apparatuses, such as an image formation apparatus.

In the second embodiment, the light-source apparatus 7 is configured to have both the bank portion 67 formed in the main body 55 of the electromagnetic shield plate 27 and the bank portion 69 formed in the case 33. However, the light-source apparatus 7 may alternatively be configured to have only one of the banks 67 and 69. In this case, it would still possible to restrain, with the only one of the banks 67 and 69, movement of the thermally-conductive member 29 toward the irradiation region 59 of the irradiation light 49.

In the above-described embodiments, the thermally-conductive member 29 is formed as a separate component from the electromagnetic shield plate 27. As an alternative, the thermally-conductive member 29 may be formed integrally with the electromagnetic shield plate 27 into one piece. As another alternative, the thermally-conductive member 29 may be formed as part of the electromagnetic shield plate 27.

In the above-described embodiments, the thermally-conductive member 29 is formed as a separate component from the metal lid 37. As an alternative, the thermally-conductive member 29 may be formed integrally with the metal lid 37 into one piece. As another alternative, the thermally-conductive member 29 may be formed as part of the metal lid 37.

In the above-described embodiments, the light-source chip drive circuit 19 is arranged outside the case 33. However, the light-source chip drive circuit 19 may alternatively be received in the case 33.

A plurality of functions realized by a single component in the above-described embodiments may alternatively be realized respectively by a plurality of components. Moreover, a single function realized by a single component in the above-described embodiments may alternatively be realized by a plurality of components together. In contrast, a plurality of functions realized respectively by a plurality of components in the above-described embodiments may alternatively be realized by a single component. Moreover, a single function realized by a plurality of components together in the above-described embodiments may alternatively be realized by a single component. Furthermore, part of the configuration of each of the above-described embodiments may be omitted. In addition, the configuration of each of the above-described embodiments may be partially added to or partially replaced with the configuration of another of the above-described embodiments.

In addition to the light-source apparatus 7 described above, the present disclosure may also be embodied in various modes such as: a system that includes the light-source apparatus 7 as a component thereof; a program for enabling a computer to function as the controller 5; a non-transitory tangible recording medium (e.g., a semiconductor memory) in which the aforementioned program is recorded; a method of dissipating heat of the light-source apparatus 7; and a heat dissipation structure of the light-source apparatus 7.

What is claimed is:

1. A light-source apparatus comprising:
a light-source chip;
a case in which the light-source chip is received;
a substrate to which the case is mounted;
an electromagnetic shield plate covering at least part of the substrate; and
a thermally-conductive member arranged to abut both the case and the electromagnetic shield plate.

2. The light-source apparatus as set forth in claim 1, wherein at least part of an outer surface of the thermally-conductive member is black in color.

3. The light-source apparatus as set forth in claim 1, wherein on at least part of an outer surface of the thermally-conductive member, the reflectivity to light irradiated by the light-source chip is lower than or equal to 5%.

4. The light-source apparatus as set forth in claim 1, wherein the thermally-conductive member is located outside an irradiation region within which light is irradiated by the light-source chip.

5. A distance measurement apparatus comprising the light-source apparatus as set forth in claim 1.
